(19) United States
(12) Patent Application Publication
(10) Pub. No.: US 2018/0219116 A1
(43) Pub. Date: Aug. 2, 2018

(54) SOLAR CELL MODULE INCLUDING A PLURALITY OF SOLAR CELLS CONNECTED AND METHOD OF MANUFACTURING A SOLAR CELL

(71) Applicant: Panasonic Intellectual Property Management Co., Ltd., Osaka (JP)

(72) Inventor: Keiichiro Masuko, Osaka (JP)

(21) Appl. No.: 15/937,273

(22) Filed: Mar. 27, 2018

Related U.S. Application Data
(63) Continuation of application No. PCT/JP2016/003700, filed on Aug. 10, 2016.

(30) Foreign Application Priority Data
Sep. 30, 2015 (JP) 2015-193285

(51) Int. Cl. H01L 31/05; H01L 31/0224; H01L 31/18

(52) U.S. Cl. CPC H01L 31/0516; H01L 31/022441; H01L 31/0481; H01L 31/022466; H01L 31/1884

(57) ABSTRACT

A solar cell module includes a plurality of solar cells. A plurality of finger electrodes for a first electrode are provided on a principal surface of a semiconductor substrate of the solar cell. A bus bar electrode for the first electrode is provided on the principal surface of the semiconductor substrate and is connected to the plurality of finger electrodes for the first electrode. The bus bar electrode for the first electrode extends beyond the semiconductor substrate toward an adjacent further solar cell. A portion of the bus bar electrode for the first electrode provided on the principal surface of the semiconductor substrate and a portion of the bus bar electrode for the first electrode extending beyond the semiconductor substrate are formed to be integrated with each other.

### CROSS-REFERENCE TO RELATED APPLICATION

This application is based upon and claims the benefit of priority from the prior Japanese Patent Application No. 2015-193285, filed on Sep. 30, 2015, the entire contents of which are incorporated herein by reference.

### BACKGROUND

### 1. Field

The disclosure relates to a solar cell module and, more particularly, to a solar cell module including a plurality of solar cells connected and a method of manufacturing a solar cell.

### 2. Description of the Related Art

Solar cells having high power generation efficiency include back surface junction type solar cells with an n-type semiconductor layer and a p-type semiconductor layer formed on a back surface, which is opposite to a light receiving surface on which light is incident. In back surface junction type solar cells, both an n-side electrode and a p-side electrode to retrieve generated power are provided on the back surface. A solar cell module is formed by electrically connecting a plurality of solar cells using wiring members (see, for example, patent document 1).

[patent document 1] Pamphlet of W013/031298

The output voltage from a single solar cell used as a power supply is not sufficient. Therefore, a solar cell module is generally configured by connecting a plurality of solar cells using wiring members. In a solar cell module, wiring members for connecting the electrodes provided in the solar cells to the plurality of solar cells are necessary in order to retrieve electric power generated in the solar cells. Provision of the wiring members makes the configuration of the solar cell module complicated and increases the manufacturing cost.

### SUMMARY

In this back ground, a general purpose of the present invention is to provide a technology of simplifying the configuration of a solar cell module.

A solar cell module according to an embodiment of the present invention comprises: a plurality of solar cells electrically connected to each other. At least one of the plurality of solar cells includes: a semiconductor substrate; a plurality of first collecting electrodes provided on a principal surface of the semiconductor substrate; and a second collecting electrode provided on the principal surface of the semiconductor substrate and connected to the plurality of first collecting electrodes. The second collecting electrode extends beyond the semiconductor substrate toward an adjacent further solar cell, and a portion of the second collecting electrode provided on the principal surface of the semiconductor substrate and a portion of the second collecting electrode extending beyond the semiconductor substrate are formed to be integrated with each other.

Another embodiment of the present invention relates to a method of manufacturing a solar cell. The method comprises: preparing a semiconductor substrate; and forming a collecting electrode by plating, the collecting electrode being provided on a principal surface of the semiconductor substrate and extending beyond the semiconductor substrate. The forming forms a portion of the collecting electrode provided on the principal surface of the semiconductor substrate and a portion extending beyond the semiconductor substrate to be integrated with each other.

### BRIEF DESCRIPTION OF THE DRAWINGS

The figures depict one or more implementations in accordance with the present teaching, by way of example only, not by way of limitations. In the figures, like reference numerals refer to the same or similar elements.

Embodiments will now be described by way of examples only, with reference to the accompanying drawings which are meant to be exemplary, not limiting and wherein like elements are numbered alike in several Figures in which:

FIG. 1 is a cross sectional view showing a structure of a solar cell module according to embodiment 1;

FIG. 2 is a plan view showing a structure of the solar cell of FIG. 1;

FIG. 3 is a cross sectional view showing a structure of the solar cell of FIG. 2;

FIGS. 4A-4C are cross sectional views showing steps of manufacturing the solar cell of FIG. 2;

FIGS. 5A-5C are cross sectional views showing manufacturing steps following those in FIGS. 4A-4C;

FIGS. 6A-6B are cross sectional views showing alternative steps of manufacturing the solar cell of FIG. 2;

FIGS. 7A-7C are cross sectional views showing still alternative steps of manufacturing the solar cell of FIG. 2;

FIG. 8 is a cross sectional view showing a structure of a solar cell module according to embodiment 2; and

FIGS. 9A-9C are plan views showing a structure of the solar cell of FIG. 8.

### DETAILED DESCRIPTION

The invention will now be described by reference to the preferred embodiments. This does not intend to limit the scope of the present invention, but to exemplify the invention.

### EMBODIMENT 1

A brief summary will be given before describing the invention in specific details. Embodiment 1 relates to a solar cell module formed by connecting a plurality of solar cells. A back surface junction type solar cell is used in a solar cell module according to embodiment 1. In a back surface junction type solar cell, a pair of comb-shaped electrodes inserted into each other are provided on the back surface opposite to a light receiving surface on which light is incident. The electrodes of this solar cell are grouped into the first electrode and the second electrode having different conductivities. To connect a plurality of solar cells, the first electrode of a given solar cell is connected by a wiring member to the second electrode of an adjacent solar cell. The larger the number of solar cells included in the solar cell module, the larger the number of wiring members required. Desirably, wiring members are not included for the purpose of simplification of the configuration of the solar cell module and cost reduction.

This is addressed in this embodiment by forming the first electrode to extend from the solar cell. With this configuration, the first electrode of a solar cell and the second electrode of an adjacent solar cell are connected. A detailed description of the embodiment will be given with reference to the drawings. In the explanations of the figures, the same elements shall be denoted by the same reference numerals, and duplicative explanations will be omitted appropriately.

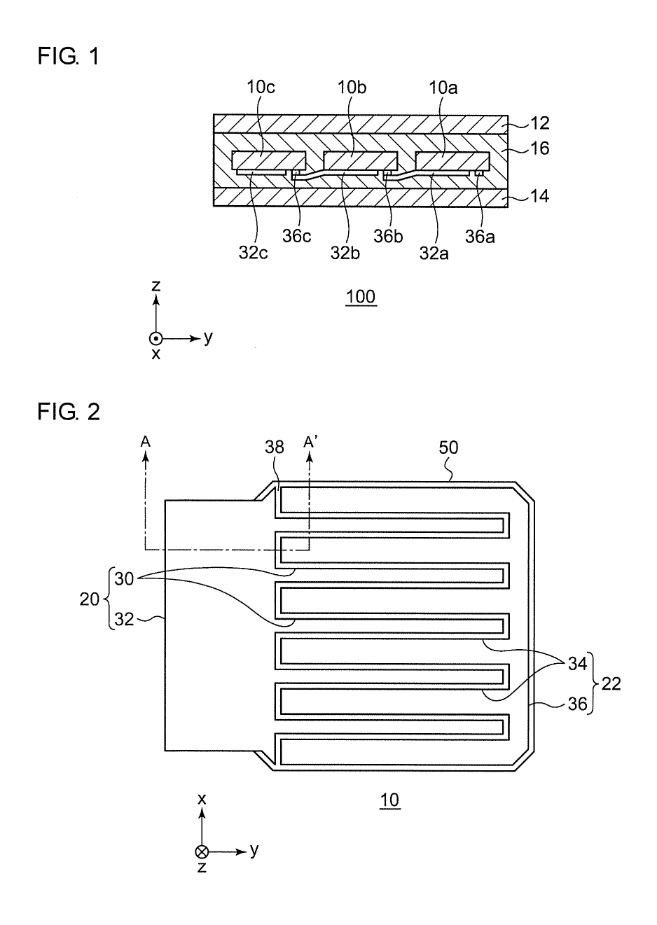

FIG. 1 is a cross sectional view showing a structure of a solar cell module 100 according to embodiment 1. The solar cell module 100 includes a first solar cell 10a, a second solar cell 10b, a third solar cell 10c, which are generically referred to as solar cells 10, a first protection member 12, a second protection member 14, and an encapsulant 16. The first solar cell 10a includes a bus bar electrode 32a for the first-first electrode and a bus bar electrode 36a for the first-second electrode. The second solar cell 10b includes a bus bar electrode 32b for the second-first electrode and a bus bar electrode 36b for the second-second electrode. The bus bar electrode 32a for the first-first electrode and the bus bar electrode 32b for the second-first electrode are generically referred to as bus bar electrodes 32 for the first electrode. The bus bar electrode 36a for the first-second electrode and the bus bar electrode 36b for the second-second electrode are generically referred to as bus bar electrodes 36 for the second electrode.

As shown in FIG. 1, a rectangular coordinate system formed by an x axis, y axis, and z axis is defined. The x axis and y axis are orthogonal to each other in the plane of the solar cell module 100. The z axis is perpendicular to the x axis and y axis and extends in the direction of thickness of the solar cell module 100. The positive directions of the x axis, y axis, and z axis are defined in the directions of arrows in FIG. 1 and the negative directions are defined in the directions opposite to those of the arrows. Of the two principal, or main, surfaces forming the solar cell module 100 that are parallel to the x-y plane, the principal surface provided on the positive direction side along the z axis is the light receiving surface, and the principal surface provided on the negative direction side along the z axis is the back surface. Hereinafter, the positive direction side along the z axis will be referred to as “light receiving surface side” and the negative direction side along the z axis will be referred to as “back surface side”.

The plurality of solar cells 10 form a solar cell string by being arranged along the y axis. The adjacent solar cells 10 are electrically connected by the bus bar electrode 32 for the first electrode of one of the solar cells 10. The configuration of the bus bar electrode 32 for the first electrode will be described later. The bus bar electrode 32 for the first electrode of one of the solar cells is adhesively bonded to the bus bar electrode 36 for the second electrode of the other solar cell 10. More specifically, the bus bar electrode 32a for the first-first electrode of the first solar cell 10a is provided to overlap the bus bar electrode 36b for the second-second electrode of the adjacent second solar cell 10b. The bus bar electrode 32a for the first-first electrode is adhesively bonded to the bus bar electrode 36b for the second-second electrode. For example, a solder or a resin adhesive agent may be used as an adhesive. The resin adhesive agent may be insulative or may have anisotropical conductivity.

The first protection member 12 is provided on the light receiving surface side of the plurality of solar cells 10. The first protection member 12 is formed of, for example, a glass or translucent resin substrate or sheet. Meanwhile, the second protection member 14 is provided on the back surface side of the plurality of solar cells 10. The second protection member 14 is formed of, for example, a resin film sandwiching a metal foil such as an aluminum foil. The encapsulant 16 is provided between the first protection member 12 and the second protection member 14. The encapsulant 16 seals the plurality of solar cells 10. The encapsulant 16 is formed of, for example, a translucent resin such as ethylene-vinyl acetate copolymer (EVA) or polyvinyl butyral (PVB).

A metal (e.g., Al) frame body (not shown) may be mounted to the outer circumference of a stack including the first protection member 12, the encapsulant 16, the solar cells 10, and the second protection member 14. Further, a wiring member and a terminal box for retrieving the output of the solar cells 10 outside may be mounted to the back surface side of the second protection member 14.

FIG. 2 is a plan view showing a structure of the solar cell 10 and shows a structure of the back surface of the solar cell 10. The solar cell 10 includes a first electrode 20, a second electrode 22, and a semiconductor substrate 50. The first electrode 20 includes a plurality of finger electrodes 30 for the first electrode and a bus bar electrode 32 for the first electrode, and the second electrode 22 includes a plurality of finger electrodes 34 for the second electrode and a bus bar electrode 36 for the second electrode. The first electrode 20 and the second electrode 22 are formed on the back surface side of the semiconductor substrate 50 and have mutually different conductivity types. To describe it more specifically, the first electrode 20 collects electrons and so is turned into a negative electrode and the second electrode 22 collects holes and so is turned into a positive electrode. Meanwhile, no electrodes are provided on the light receiving surface side. Therefore, the solar cell 10 is a back surface junction type photovoltaic device.

The plurality of finger electrodes 30 for the first electrode are formed in a rectangular shape extending in the y axis direction. It is assumed here that the number of finger electrodes 30 for the first electrode is “5” but the number is not limited thereto. The bus bar electrode 32 for the first electrode is connected to the ends of the plurality of finger electrodes 30 for the first electrode on the negative direction side along the y axis. The bus bar electrode 32 for the first electrode is formed in a trapezoidal shape extending in the x axis direction in the semiconductor substrate 50. Further, the bus bar electrode 32 for the first electrode extends beyond the semiconductor substrate 50 toward the adjacent further solar cell 10 (not shown) provided on the negative direction side of the solar cell 10 along the y axis. The portion extending beyond the semiconductor substrate 50 in the negative direction of the y axis is formed in a rectangular shape. Further, the trapezoidal portion of the bus bar electrode 32 for the first electrode provided in the semiconductor substrate 50 and the portion of the bus bar electrode 32 for the first electrode extending beyond the semiconductor substrate 50 are formed to be integrated with each other.

In the case that the back surface of the solar cell 10 is formed in a rectangular shape, the bus bar electrode 32 for the first electrode may also be formed in a rectangular shape as a whole. The first electrode 20 is formed in a comb-tooth shape by the combination of the plurality of finger electrodes 30 for the first electrode and the bus bar electrode 32 for the first electrode. Defining the y axis as the first direction, the x direction can be defined as the second direction perpendicular to the first direction.

The plurality of finger electrodes 34 for the second electrode are formed in a rectangular shape extending in the y axis direction. It is assumed here that the number of finger electrodes 34 for the second electrode is “6” but the number is not limited thereto. The bus bar electrode 36 for the second electrode is connected to the ends of the plurality of finger electrodes 34 for the second electrode on the positive direction side along the y axis. The bus bar electrode 36 for the second electrode is formed in a trapezoidal shape extending in the x axis direction. The bus bar electrode 36 for the second electrode may be formed in a rectangular shape as in the case of the bus bar electrode 32 for the first electrode. Unlike the bus bar electrode 32 for the first electrode, the bus bar electrode 36 for the second electrode is provided only in the semiconductor substrate 50 and does not extend beyond the semiconductor substrate 50. The second electrode 22 is also formed in a comb-tooth shape by the combination of the plurality of finger electrodes 34 for the second electrode and the bus bar electrode 36 for the second electrode.

The first electrode 20 and the second electrode 22 are formed so as to cause the plurality of finger electrodes 30 for the first electrode and the plurality of finger electrodes 34 for the second electrode to be engaged with each other and inserted into each other. An isolation area 38 is provided between the first electrode 20 and the second electrode 22. The isolation area 38 is provided to ensure isolation between the first electrode 20 and the second electrode 22 and is formed to meander along the comb shape of the first electrode 20 and the second electrode 22. The transparent conductive layer and the metal electrode layer described later that form the first electrode 20 and the second electrode 22 are not provided in the isolation area 38. For this reason, the transparent conductive layer and the metal electrode layer are provided to respectively correspond to the first electrode 20 and the second electrode 22.

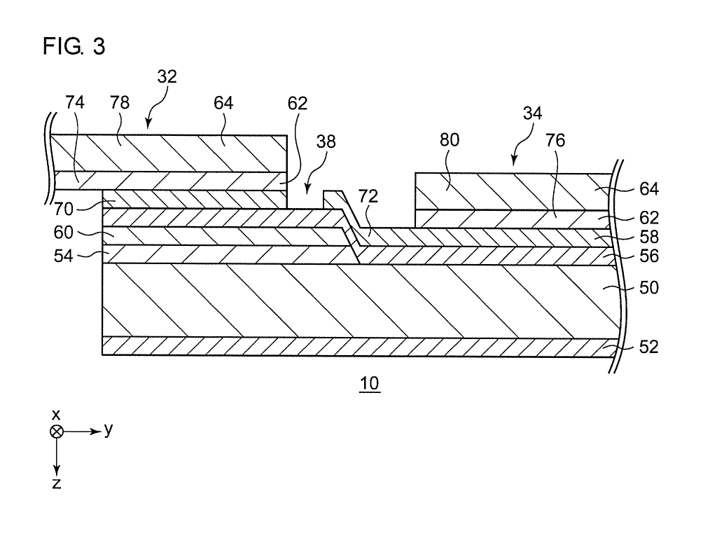

FIG. 3 is an A-A′ cross sectional view showing a structure of the solar cell 10. In other words, FIG. 3 is a cross sectional view of a portion of FIG. 2 in which the bus bar electrode 32 for the first electrode, the finger electrode 34 for the second electrode, and the isolation area 38 are provided. The solar cell 10 includes the semiconductor substrate 50, a protection layer 52, a first semiconductor layer 54, a second semiconductor layer 56, a transparent conductive layer 58, an insulating layer 60, a seed layer 62, and a plating layer 64. The transparent conductive layer 58 includes a first transparent conductive layer 70 and a second transparent conductive layer 72, the seed layer 62 includes a first seed layer 74 and a second seed layer 76, and the plating layer 64 includes a first plating layer 78 and a second plating layer 80. The metal electrode layer formed by the seed layer 62 and the plating layer 64, and the transparent conductive layer 58 form the bus bar electrode 32 for the first electrode and the finger electrode 34 for the second electrode.

The semiconductor substrate 50 absorbs light incident on the positive direction side along the z axis, i.e., on the light receiving surface side and generates electrodes and holes as carriers. The semiconductor substrate 50 is formed of a crystalline semiconductor material of an n-type or p-type conductivity. The semiconductor substrate 50 in the embodiment is assumed to be an n-type monocrystalline silicon wafer. The back surface side of the semiconductor substrate 50, on which the bus bar electrode 32 for the first electrode, the finger electrode 34 for the second electrode, the finger electrode 30 for the first electrode (not shown), and the bus bar electrode 36 for the second electrode (not shown) are provided, opposite to the light receiving surface side is not provided with collecting electrodes.

The protection layer 52 is provided on the positive direction side of the semiconductor substrate 50 along the z axis. The protection layer 52 is formed of, for example, silicon, silicon oxide, silicon nitride, silicon oxynitride, or the like. The protection layer 52 has a function of a passivation layer for the light receiving surface of the semiconductor substrate 50 and a function of an antireflection film and a protection film. The protection layer 52 has a structure in which an i-type amorphous silicon layer, an insulating layer of silicon oxide or silicon nitride, etc. are stacked in sequence on the light receiving surface of the semiconductor substrate 50. The protection layer 52 may have a structure in which an n-type amorphous silicon layer is provided between an i-type amorphous silicon layer and an insulating layer. The i-type amorphous silicon layer and the n-type amorphous silicon layer have a thickness of, for example, about 2 nm˜50 nm. The insulating layer of silicon oxide, silicon nitride, or silicon oxynitride or the like has a thickness of, for example, about 50 nm˜200 nm.

The first semiconductor layer 54 and the second semiconductor layer 56 are formed on the back surface side of the semiconductor substrate 50. Each of the first semiconductor layer 54 and the second semiconductor layer 56 is formed in a comb-tooth shape in alignment with the first electrode 20 and the second electrode 22 (not shown), respectively. The first semiconductor layer 54 and the second semiconductor layer 56 are formed so as to be inserted into each other.

The first semiconductor layer 54 is a semiconductor layer having a first conductivity type and is formed of an amorphous semiconductor layer having an n-type conductivity like the semiconductor substrate 50. The first semiconductor layer 54 is comprised of a dual structure including, for example, a substantially intrinsic i-type amorphous semiconductor layer formed on the light receiving surface and an n-type amorphous semiconductor layer formed on the i-type amorphous semiconductor layer. In this embodiment, an “amorphous semiconductor” may include a microcrystalline semiconductor. The term microcrystalline semiconductor encompasses semiconductor crystal grains in an amorphous semiconductor.

The i-type amorphous semiconductor layer is formed of an i-type amorphous silicon containing hydrogen (H) and has a thickness of, for example, about 2 nm˜25 nm. The n-type amorphous semiconductor layer is formed of an n-type amorphous silicon containing hydrogen doped with an n-type dopant and has a thickness of, for example, about 2 nm˜50 nm. The method of forming the layers forming the first semiconductor layer 54 is not particularly limited. For example, the layers may be formed by a chemical vapor deposition (CVD) method such as a plasma CVD method.

The insulating layer 60 is formed on the back surface side of the first semiconductor layer 54. The insulating layer 60 is provided in a portion where the bus bar electrode 32 for the first electrode is provided but is not provided in a portion where the finger electrode 34 for the second electrode is provided. Therefore, a step difference is provided between the bus bar electrode 32 for the first electrode and the finger electrode 34 for the second electrode. The insulating layer 60 is formed of, for example, silicon oxide (SiO₂), silicon nitride (SiN), silicon oxynitride (SiON), or the like. The insulating layer 60 is desirably formed of silicon nitride.

The second semiconductor layer 56 is formed in a portion on the back surface side of the semiconductor substrate 50 not provided with the first semiconductor layer 54 and is provided to overlap the first semiconductor layer 54 on the negative direction side along the z axis in the portion provided with the first semiconductor layer 54. The second semiconductor layer 56 has a second conductivity type and is comprised of an amorphous semiconductor layer having a p-type conductivity type different from that of the semiconductor substrate 50. The second semiconductor layer 56 is comprised of a dual structure including, for example, a substantially intrinsic i-type amorphous semiconductor layer formed on the back surface side of the semiconductor substrate 50 and a p-type amorphous semiconductor layer formed on the i-type amorphous semiconductor layer. In the embodiment shown in FIG. 3, the first semiconductor layer 54 and the second semiconductor layer 56 are provided to sandwich the insulating layer 60 in the area provided with the bus bar electrode 32 for the first electrode. In this area, the semiconductor layer 56 may be removed, or the semiconductor layer 56 and the insulating layer 60 may be removed.

The i-type amorphous semiconductor layer is formed of an i-type amorphous silicon containing hydrogen (H) and has a thickness of, for example, about 2 nm˜25 nm. The p-type amorphous semiconductor layer is formed of an n-type amorphous silicon containing hydrogen doped with a p-type dopant and has a thickness of, for example, about 2 nm˜50 nm. The method of forming the layers of the second semiconductor layer 56 is not particularly limited. For example, the layers may be formed by a chemical vapor deposition (CVD) method such as a plasma CVD method.

The bus bar electrode 32 for the first electrode is formed on the first semiconductor layer 54. The finger electrode 34 for the second electrode for collecting holes is formed on the semiconductor layer 56. The isolation area 38 is formed between the bus bar electrode 32 for the first electrode and the finger electrode 34 for the second electrode so that the electrodes are electrically insulated from each other. As described above, the bus bar electrode 32 for the first electrode and the finger electrode 34 for the second electrode are are each formed of a stack of the transparent conductive layer 58 and the metal electrode layer described later.

The transparent conductive layer 58 is formed on the back surface side of the second semiconductor layer 56. The transparent conductive layer 58 is not provided in the isolation area 38. Therefore, the transparent conductive layer 58 is isolated into the first transparent conductive layer 70 included in the bus bar electrode 32 for the first electrode and the second transparent conductive layer 72 included in the finger electrode 34 for the second electrode. The transparent conductive layer 58 is formed of, for example, a transparent conductive oxide (TCO) such as a tin oxide (SnO₂), a zinc oxide (ZnO), an indium tin oxide (ITO), or the like. The transparent conductive layer 58 according to this embodiment is formed of an indium tin oxide and has a thickness of, for example, about 50 nm˜100 nm. The transparent conductive layer 58 can be formed by a thin film formation method such as sputtering and chemical vapor deposition (CVD).

The seed layer 62 is formed on the negative direction side of the transparent conductive layer 58 along the z axis. To describe it in details, the first seed layer 74 is formed on the negative direction side of the first transparent conductive layer 70 along the z axis, and the second seed layer 76 is formed on the negative direction side of the second transparent conductive layer 72 along the z axis. In particular, the first seed layer 74 is not only formed in the portion provided with the first transparent conductive layer 70 but also formed to extend in the negative direction in the y axis direction from the portion provided with the first transparent conductive layer 70. In other words, the first seed layer 74 is also provided in a portion on the x-y plane not provided with the semiconductor substrate 50. The length of the portion of the first seed layer 74 extending in the negative direction in the y axis direction is configured to be longer than the distance to a further solar cell 10 provided in that direction. Meanwhile, the second seed layer 76 is formed only in the portion provided with the second transparent conductive layer 72.

The seed layer 62 forms a metal electrode layer along with the plating layer 64 described later, and the metal electrode layer is formed of a metal material such as copper (Cu), tin (Sn), gold (Au), silver (Ag), nickel (Ni), and titanium (Ti). It is assumed here that the metal electrode layer is formed of copper. The seed layer 62 has a thickness of, for example, about 50 nm˜1000 nm. Further, the seed layer 62 is formed by a thin film formation method such as sputtering and chemical vapor deposition (CVD).

The plating layer 64 is formed on the negative direction side of the seed layer 62 along the z axis. To describe it more specifically, the first plating layer 78 is formed on the negative direction side of the first seed layer 74 along the z axis, and the second plating layer 80 is formed on the negative direction side of the second seed layer 76 along the z axis. Therefore, like the first seed layer 74, the first plating layer 78 is provided in a portion on the x-y plane not provided with the semiconductor substrate 50, and, like the second seed layer 76, the second plating layer 80 is provided only in the portion on the x-y plane provided with the semiconductor substrate 50. The plating layer 64 is formed by plating and has a thickness of about 10 μm˜50 μm.

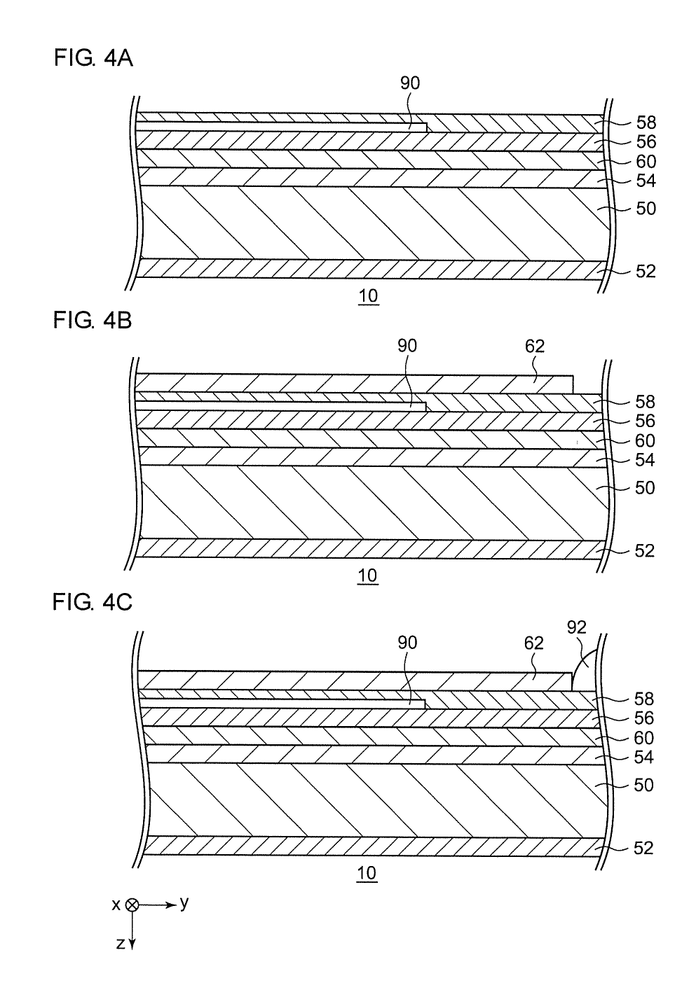

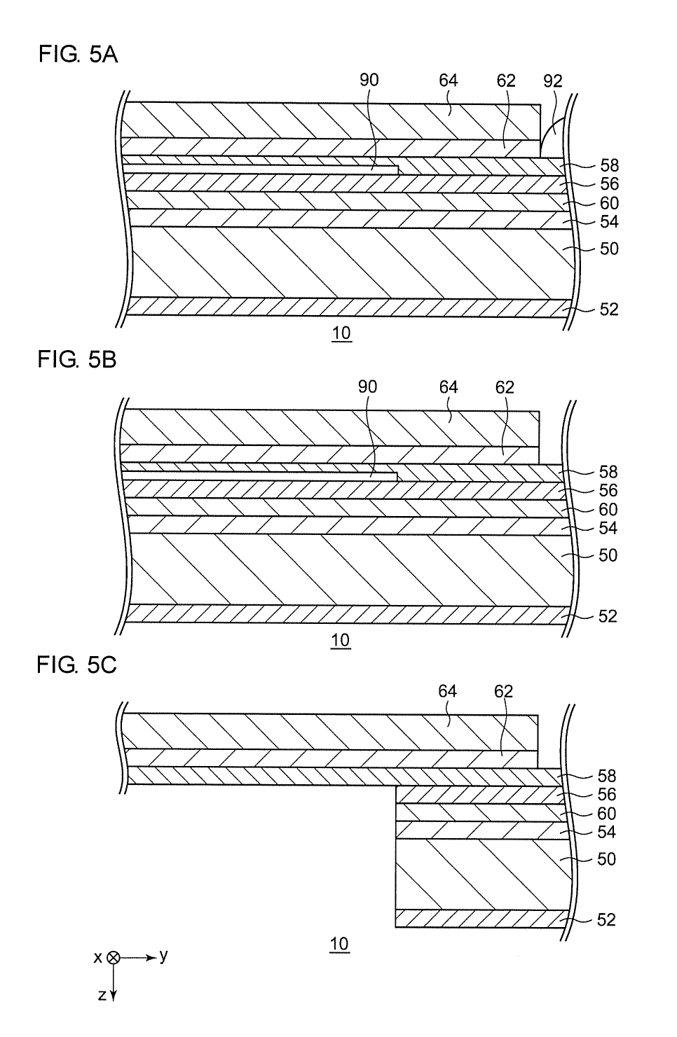

A description will hereinafter be given of a method of manufacturing the solar cell 10 with reference to FIGS. 4A-4C and FIGS. 5A-5C. FIGS. 4A-4C are cross sectional views showing steps of manufacturing the solar cell 10, and, in particular, the bus bar electrode 32 for the first electrode. As shown in FIG. 4A, the semiconductor substrate 50 is prepared. In this case, a preparatory semiconductor substrate 50 having a principal surface of a size larger than the size of the principal surface of the ultimate semiconductor substrate 50 shown in FIGS. 2 and 3 is prepared. The preparatory semiconductor substrate 50 has a size capable of accommodating the entirety of the bus bar electrode 32 for the first electrode shown in FIG. 2.

The protection layer 52 is built on the light receiving surface side of the semiconductor substrate 50. Further, the first semiconductor layer 54 is built on the back surface side of the semiconductor substrate 50, the insulating layer 60 is built on the back surface side of the first semiconductor layer 54, and the semiconductor layer 56 is built on the back surface side of the insulating layer 60. Further, the transparent conductive layer 58 is built on the back surface side of the second semiconductor layer 56. A resist 90 is provided between the portion of the second semiconductor layer 56 ultimately extending beyond the semiconductor substrate 50 and the transparent conductive layer 58. The resist 90 is a layer that facilitates later separation between the second semiconductor layer 56 and the transparent conductive layer 58. The method of forming the protection layer 52, the first semiconductor layer 54, the insulating layer 60, the second semiconductor layer 56, and the transparent conductive layer 58 is not particularly limited. For example, the layers can be formed by a thin film formation method such as sputtering and chemical vapor deposition (CVD). The first semiconductor layer 54, the insulating layer 60, and the second semiconductor layer 56 are removed in part by etching or laser irradiation so as to form the plurality of finger electrodes 30 for the first electrode and the plurality of finger electrodes 34 for the second electrode to be engaged with each other and inserted into each other.

Subsequently, as shown in FIG. 4B, the seed layer 62 is built on the back surface side of the transparent conductive layer 58. The seed layer 62 is also formed by sputtering etc. Subsequently, as shown in FIG. 4C, a resist 92 is provided in a portion other than where the plating layer 64 is formed. Provision of the resist 92 represents resist patterning.

FIGS. 5A-SC are cross sectional views showing manufacturing steps following those in FIGS. 4A-4C. As shown in FIG. 5A, the plating layer 64 is formed on the back surface side of the seed layer 62 by plating. In other words, since the seed layer 62 is provided on the principal surface of the preparatory semiconductor substrate 50, the plating layer 64 is also provided on the principal surface of the preparatory semiconductor substrate 50. Subsequently, the resist 92 is removed as shown in FIG. 5B. A publicly known technology may be used for removal of the resist 92.

Finally, as shown in FIG. 5C, portions of the semiconductor substrate 50, the protection layer 52, the first semiconductor layer 54, the insulating layer 60, and the second semiconductor layer 56, and, more specifically, portions on the negative direction side along the y axis, are cut so as to result in the size of the principal surface of the ultimate semiconductor substrate 50. The cut portions are portions where the resist 90 is provided between the second semiconductor layer 56 and the transparent conductive layer 58. The portions are cut by laser cutting. Further, the resist 90 is removed. It can be said that, through these steps, the portion of the plating layer 64 provided on the principal surface of the semiconductor substrate 50 and the portion extending beyond the semiconductor substrate 50 are formed in an integral manner by plating. The resist 90 may not be provided between the second semiconductor layer 56 and the transparent conductive layer 58. For example, the resist 90 may be provided between the transparent conductive layer 58 and the seed layer 62.

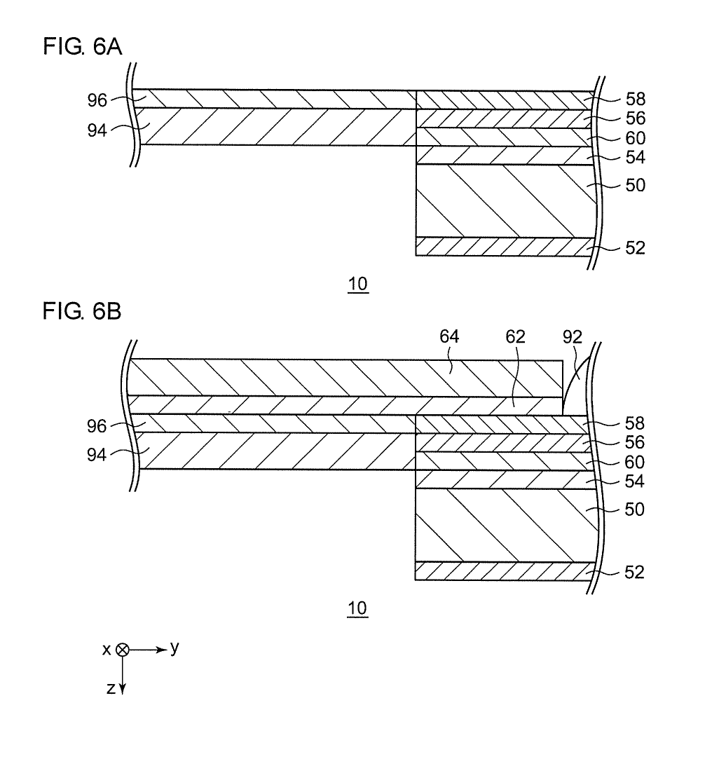

A description will be given of a method of manufacturing the solar cell 10 different from that of FIGS. 4A-4C and 5A-5C, with reference to FIGS. 6A-6B. FIGS. 6A-6B are cross sectional views showing alternative steps of manufacturing the solar cell 10, and, in particular, the bus bar electrode 32 for the first electrode. As shown in FIG. 6A, a stack, in which the protection layer 52, the semiconductor substrate 50, the first semiconductor layer 54, the insulating layer 60, the second semiconductor layer 56, and the transparent conductive layer 58 are built in the positive-to-negative direction along the z axis (hereinafter, referred to as a “first stack”), is formed. The size of the semiconductor substrate 50 in the stack is different from that of FIG. 4A and is the size of the ultimate semiconductor substrate 50.

A stack in which an auxiliary sheet 94 and a copper paste 96 are built in the positive-to-negative direction along the z axis (hereinafter, referred to as a “second stack”) is arranged beside the first stack. The back surface of the first surface and the back surface of the second stack are aligned such that the copper paste 96 and the transparent conductive layer 58 are substantially flush with each other on the negative direction side along the z axis. The term “substantially” means accommodating a range of errors. A resin (e.g., PET) sheet is used for the auxiliary sheet 94. The copper paste 96 has relatively low intimacy of contact with the auxiliary sheet 94. So long as such property is provided, an alternative to the copper paste 96 may be used.

Subsequently, the seed layer 62 is formed on the back surface side of the transparent conductive layer 58 and the copper paste 96. Resist patterning for providing the resist 92 is performed in a portion other than where the plating layer 64 is formed. Further, the plating layer 64 is formed on the back surface side of the seed layer 62 by plating. Thus, the plating layer 64 is formed on the principal surface of the first stack and the principal surface of the second stack by plating.

The portions of the seed layer 62 and the plating layer 64 formed on the back surface side of the first stack correspond to the portions of the bus bar electrode 32 for the first electrode provided in the semiconductor substrate 50. Further, the portions of the seed layer 62 and the plating layer 64 formed on the back surface side of the second stack correspond to the portions of the bus bar electrode for the first electrode 32 extending beyond the semiconductor substrate 50. These steps correspond to those in FIGS. 4B-4C and FIG. 5A.

Further, after the resist 92 is removed, the auxiliary sheet 94 is removed from the first stack. As mentioned previously, the intimacy of contact between the copper paste 96 and auxiliary sheet 94 is relatively low so that it is easy to remove the auxiliary sheet 94.

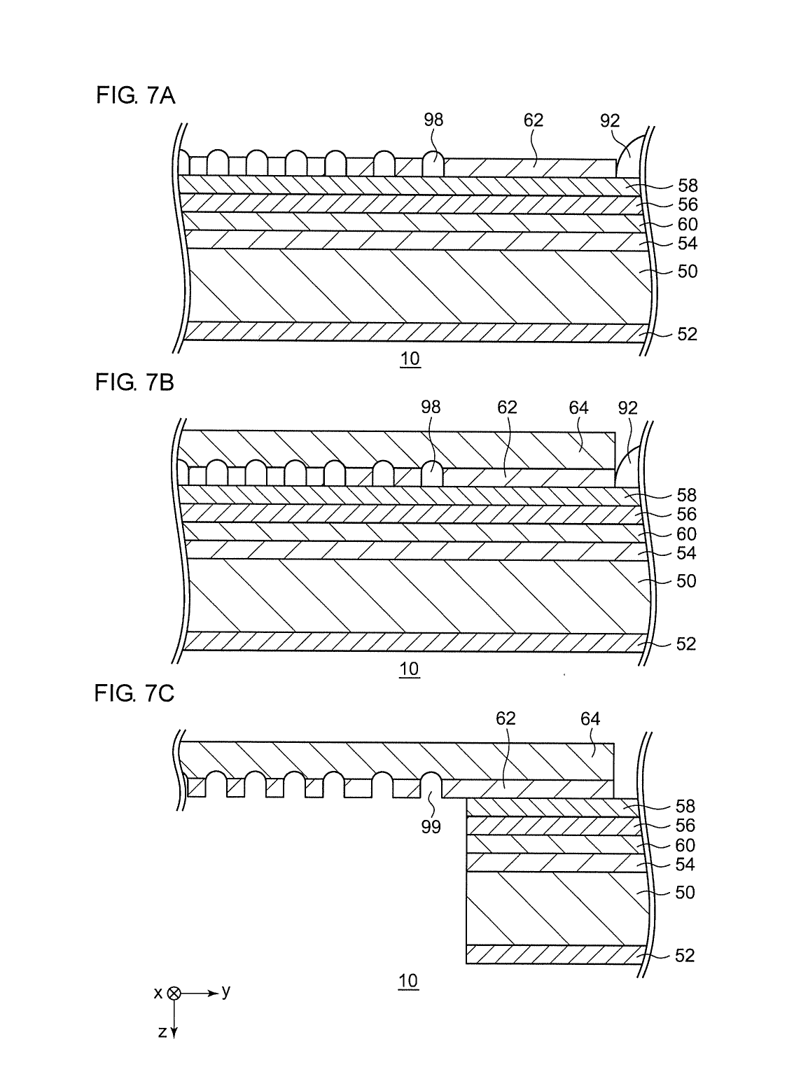

A description will be given of a method of manufacturing the solar cell 10 different from the methods described so far, with reference to FIGS. 7A-7C. FIGS. 7A-7C are cross sectional views showing still alternative steps of manufacturing the solar cell 10, and, in particular, the bus bar electrode 32 for the first electrode. In FIG. 7A, as in FIG. 4A, the protection layer 52, the semiconductor substrate 50, the first semiconductor layer 54, the insulating layer 60, the second semiconductor layer 56, and the transparent conductive layer 58 are built in the positive-to-negative direction along the z axis.

A plurality of resists 98 are formed in a portion of the back surface side of the transparent conductive layer 58 not included in the ultimate semiconductor substrate 50. The resists 98 are formed in a bar shape elongated in the x axis direction and are arranged at a regular interval in the y axis direction. Further, the seed layer 62 is formed on the back surface side of transparent conductive layer 58 so as to avoid the resists 98. Resist patterning for providing the resist 92 is performed in a portion other than where the plating layer 64 is formed.

As shown in FIG. 7B, the plating layer 64 is then formed on the back surface side of the seed layer 62 and the resist 98 by plating. Subsequently, the resist 92 and the resists 98 are removed as shown in FIG. 7C. By removing the resists 98, the portions in the seed layer 62 and the plating layer 64 where the plurality of resists 98 are provided are formed with a plurality of grooves 99. By forming the plurality of grooves 99, the area of contact between the seed layer 62 and the transparent conductive layer 58 is reduced.

Further, portions of the semiconductor substrate 50, the protection layer 52, the first semiconductor layer 54, the insulating layer 60, the second semiconductor layer 56, and the transparent conductive layer 58, and, more specifically, portions on the negative direction side along the y axis, are cut so as to result in the size of the principal surface of the ultimate semiconductor substrate 50. The cut portions are portions where the plurality of grooves 99 are provided. The portions are cut by laser cutting. The portions where the area of contact between the seed layer 62 and the transparent conductive layer 58 is reduced are cut so that it is easy to remove the transparent conductive layer 58 as cut from the seed layer 62.

According to this embodiment, the portion of the bus bar electrode for the first electrode provided on the principal surface of the semiconductor substrate and the portion extending beyond the semiconductor substrate are formed to be integrated with each other. Therefore, the bus bar electrode for the first electrode can be used to connect a plurality of solar cells. Since the bus bar electrode for the first electrode is used to connect a plurality of solar cells, wiring members are not necessary. Since wiring members are not necessary, the configuration of the solar cell module is simplified. Since wiring members are not necessary, the cost of manufacturing the solar cell can be reduced.

Since the portion of the bus bar electrode for the first electrode provided on the principal surface of the semiconductor substrate and the portion extending beyond the semiconductor substrate are formed to be integrated with each other by plating, manufacturing is simplified. Since the preparatory semiconductor substrate having a principal surface of a size larger than the size of the principal surface of the ultimate semiconductor substrate is prepared and portions of the preparatory semiconductor substrate are cut to result in the size of the principal surface of the ultimate semiconductor substrate, the portions extending beyond the semiconductor substrate can be formed easily. Since the the auxiliary sheet is arranged on the semiconductor substrate and the auxiliary sheet is removed from the semiconductor substrate, it is easy to form the portion extending beyond the semiconductor substrate.

One embodiment of the present invention is summarized below. A solar cell module 100 according to an embodiment of the present invention comprises a plurality of solar cells 10 electrically connected to each other. At least one of the plurality of solar cells 10 includes: a semiconductor substrate 50, a plurality of finger electrodes 30 for the first electrode provided on a principal surface of the semiconductor substrate 50, and a bus bar electrode 32 for the first electrode provided on the principal surface of the semiconductor substrate 50 and connected to the plurality of finger electrodes 30 for the first electrode. The bus bar electrode 32 for the first electrode extends beyond the semiconductor substrate 50 toward an adjacent further solar cell 10, and a portion of the bus bar electrode 32 for the first electrode provided on the principal surface of the semiconductor substrate 50 and a portion of the bus bar electrode 32 for the first electrode extending beyond the semiconductor substrate are formed to be integrated with each other.

The solar cell 10 may be a back surface junction type solar cell, and collecting electrodes may not be provided on a principal surface of the semiconductor substrate 50 opposite to the principal surface on which the finger electrodes 30 for the first electrode and the bus bar electrode 32 for the second electrode are provided.

The bus bar electrode 32 for the first electrode may be bonded to an adjacent further solar cell 10 in an area overlapping the adjacent further solar cell 10 using an adhesive.

Another embodiment of the present invention relates to a method of manufacturing a solar cell 10. The method comprises: preparing a semiconductor substrate 50; and forming a bus bar electrode 32 for the first electrode by plating, the bus bar electrode 32 for the first electrode being provided on a principal surface of the semiconductor substrate 50 and extending beyond the semiconductor substrate 50. The forming forms a portion of the bus bar electrode 32 for the first electrode provided on the principal surface of the semiconductor substrate 50 and a portion of the bus bar electrode 32 for the first electrode extending beyond the semiconductor substrate 50 to be integrated with each other.

The preparing may prepare a preparatory semiconductor substrate 50 having a principal surface of a size larger than an size of the principal surface of an ultimate semiconductor substrate 50, and the forming may include: forming the bus bar electrode 32 for the first electrode on the principal surface of the preparatory semiconductor substrate 50 by plating; and cutting a portion of the preparatory semiconductor substrate 50 so as to result in the size of the principal surface of the ultimate semiconductor substrate 50.

The preparing may arrange an auxiliary sheet 94 on the semiconductor substrate 50 while aligning the principal surface of the semiconductor substrate 50 and a principal surface of the auxiliary sheet 94, and the forming may include: forming the bus bar electrode 32 for the first electrode on the principal surface of the semiconductor substrate 50 and on the principal surface of the auxiliary sheet 94 by plating; and removing the auxiliary sheet 94 from the semiconductor substrate 50.

### Embodiment 2

A description will now be given of embodiment 2. Like embodiment 1, embodiment 2 relates to a solar cell module formed by connecting a plurality of solar cells. In embodiment 1, the back surface junction type solar cell is used. In embodiment 2, a solar cell in which electrodes are provided both on the light receiving surface side and on the back surface side is used. In other words, the first electrode and the second electrode are provided in part on the light receiving surface and in part on the back surface. Further, for connection of a plurality of solar cells, the first electrode of a given solar cell is connected to the second electrode of an adjacent solar cell by a wiring member. The larger the number of solar cells included in the solar cell module, the larger the number of wiring members required. Desirably, wiring members are not included for the purpose of simplification of the configuration of the solar cell module and cost reduction.

This is addressed in this embodiment by forming the electrode provided on the light receiving surface side of the solar cell to extend from the solar cell. With this configuration, the electrode of a solar cell provided on the light receiving surface side and the electrode provided on the back surface side of the adjacent solar cell are directly connected. The following description concerns a difference from the embodiments described above.

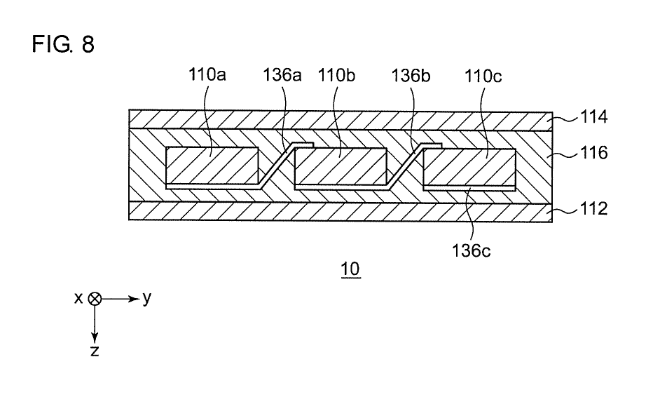

FIG. 8 is a cross sectional view showing a structure of a solar cell module 100 according to embodiment 2. The solar cell module 100 includes a first solar cell 110a, a second solar cell 110b, a third solar cell 110c, which are generically referred to as solar cells 110, a first protection member 112, a second protection member 114, and an encapsulant 116. The first solar cell 110a includes a first bus bar electrode 136a and the second solar cell 110b includes a second bus bar electrode 136b. The first bus bar electrode 136a and the second bus bar electrode 136b are generically referred to as bus bar electrodes 136.

The plurality of solar cells 110 form a solar cell string by being arranged along the y axis. The adjacent solar cells 110 are electrically connected by the bus bar electrode 132 of one of the solar cells 110. In particular, the bus bar electrode 136 extends beyond the light receiving surface side of one of the solar cells 110 and is connected to the back surface side of another solar cell 110. An adhesive is used for connection. The first protection member 112, the second protection member 114, and the encapsulant 116 are configured similarly as the first protection member 12, the second protection member 14, and the encapsulant 16. The second protection member 114 may be configured similarly as the first protection member 112.

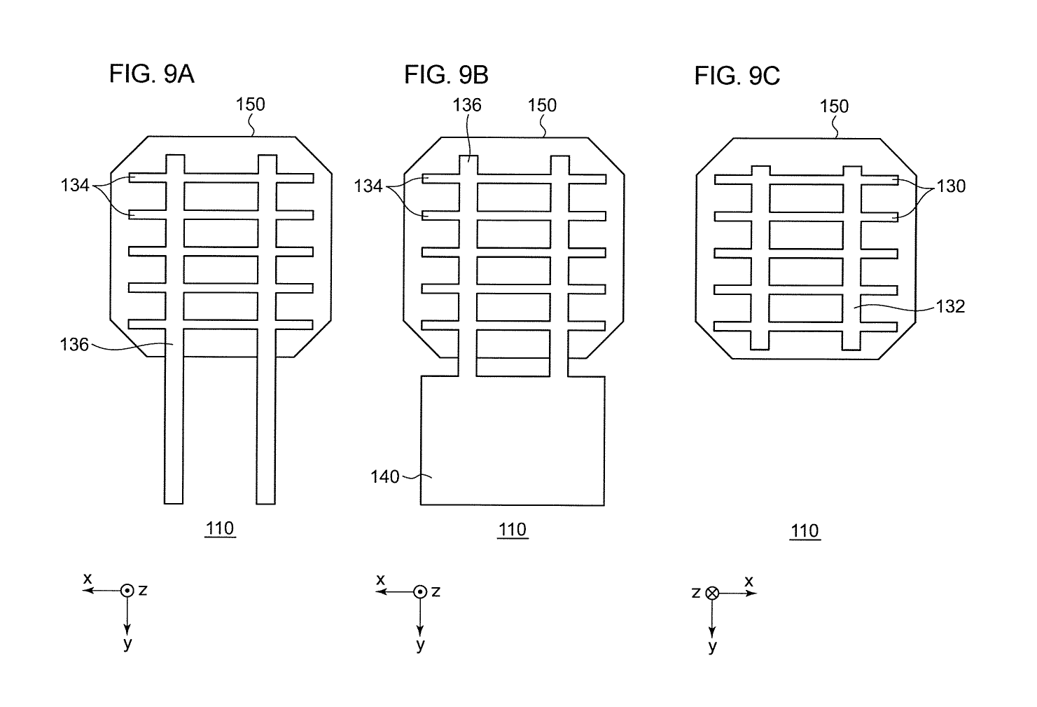

FIGS. 9A-9C are plan views showing a structure of the solar cell 110. FIG. 9A shows a surface of the solar cell 110 on the light receiving surface side. A finger electrode 134 extends in the x axis direction. A plurality of finger electrodes 134 are arranged in parallel in the y axis direction. Each of the finger electrodes 134 is provided in a semiconductor substrate 150 and does not extend beyond the semiconductor substrate 150. Meanwhile, two bus bar electrodes 136 extend in the y axis direction so as to be substantially perpendicular to the plurality of finger electrodes 134, and the two bus bar electrodes 136 are provided in parallel in the x axis direction. The bus bar electrodes 136 extend beyond the semiconductor substrate 150 on the positive direction side along the y axis.

The finger electrodes 134 and the bus bar electrodes 136 are formed by plating similarly as the finger electrodes 30 for the first electrode, the bus bar electrode 32 for the first electrode, the finger electrodes 34 for the second electrode, and the bus bar electrode 36 for the second electrode. The number of finger electrodes 134 is not limited to “5” as shown, and the number of bus bar electrodes 136 is not limited to “2” as shown.

FIG. 9B shows an alternative surface on the light receiving surface side of the solar cell 110. The difference from the solar cell 110 shown in FIG. 9A is that the end of the bus bar electrode 132 in the y axis is configured as a connection plate 140. The solar cell 110 is formed in a rectangular shape on the x-y plane. The connection plate 140 is also formed by plating similarly as the bus bar electrode 132.

FIG. 9C shows a surface of the solar cell 110 on the back surface side. A finger electrode 130 extends in the x axis direction. A plurality of finger electrodes 130 are arranged in parallel in the y axis direction. Further, the two bus bar electrodes 132 extend in the y axis direction so as to be substantially perpendicular to the plurality of finger electrodes 130, and the two bus bar electrodes 132 are provided in parallel in the x axis direction. An adhesive is used for connection. The finger electrodes 130 and the bus bar electrodes 132 on the light receiving surface side do not extend beyond the semiconductor substrate 150.

The bus bar electrode 136 or the connection plate 140 from an adjacent further solar cell 110 is connected to the bus bar electrodes 132. The finger electrodes 130 and the bus bar electrodes 132 are formed by screen printing but may be formed by plating. The number of finger electrodes 130 is not limited to “5” as shown, and the number of bus bar electrodes 132 is not limited to “2” as shown.

The solar cell 110, and, in particular, the bus bar electrodes 136 and the connection plate 140, may be manufactured similarly as in the case of embodiment 1. For example, as in FIGS. 4A-4C and FIGS. 5A-5C, the preparatory semiconductor substrate 150 of a size larger than the size of the ultimate semiconductor substrate 150 may be prepared and the preparatory semiconductor substrate 150 may be cut to result in the size of the ultimate semiconductor substrate 150. Further, as in FIGS. 6A-6B, the auxiliary sheet 94 may be arranged on the semiconductor substrate 150 and the auxiliary sheet 94 may be removed ultimately. Further, as in FIGS. 7A-7C, the grooves 99 may be formed in the bus bar electrodes 136 and the connection plate 140. A publicly known technology may be used to manufacture the parts of the solar cell 110 other than the bus bar electrodes 136 and the connection plate 140.

According to this embodiment, the bus bar electrodes are used to connect a plurality of solar cells so that wiring members are not necessary. Since wiring members are not necessary, the configuration of the solar cell module is simplified. Since wiring members are not necessary, the cost of manufacturing the solar cell can be reduced.

One embodiment of the present invention is summarized below. The finger electrodes 130 and the bus bar electrodes 132 provided on the principal surface of the semiconductor substrate 150 opposite to the principal surface on which the finger electrodes 134 and the bus bar electrodes 136 are provided may not extend beyond the semiconductor substrate 150.

Described above is an explanation based on an exemplary embodiment. The embodiment is intended to be illustrative only and it will be understood by those skilled in the art that various modifications to constituting elements and processes could be developed and that such modifications are also within the scope of the present invention.

In embodiments 1 and 2, the preparatory semiconductor substrate 50 or the semiconductor substrate 150 having a relatively large size, and the auxiliary sheet 94 are used in order to form electrodes that extend beyond the semiconductor substrate 50. Alternatively, a metal sheet may be adhesively attached to the semiconductor substrate 50 or the semiconductor substrate 150. For adhesive attachment, laser welding, ultrasonic waves, Ar plasma, or the like is used. According to this variation, the flexibility of manufacturing is improved.

In embodiments 1 and 2, the copper paste 96 is used to facilitate removal of the auxiliary sheet 94. Alternatively, a resin plate that is removed in the presence of a solvent may be used. According to this variation, the flexibility of manufacturing is improved.

In embodiment 1, the bus bar electrode 32 for the first electrodes is configured to extend beyond the semiconductor substrate 50. Alternatively, the bus bar electrode 36 for the second electrode may be configured to extend beyond the semiconductor substrate 50, or both the bus bar electrode 32 for the first electrode and the bus bar electrode 36 for the second electrode may be configured to extend beyond the semiconductor substrate 50. It is preferable that only one of the bus bar electrode 32 for the first electrode and the bus bar electrode 36 for the second electrode be configured to extend beyond the semiconductor substrate 50 and the area connecting the first electrode 20 and the second electrode be hidden by overlapping with the solar cell 10.

In embodiment 2, the bus bar electrode 136 provided on the light receiving surface side is formed to extend beyond the semiconductor substrate 150. However, the bus bar electrode 132 provided on the back surface side may be formed to extend beyond the semiconductor substrate 150, or both the bus bar electrode 136 and the bus bar electrode 132 may be formed to extend beyond the semiconductor substrate 150. However, it is preferable that, as in embodiment 2, only the bus bar electrode 136 provided on the light receiving surface side be formed to extend beyond the semiconductor substrate 150 and the area connecting the bus bar electrode 136 and the bus bar electrode 132 be hidden by overlapping with the semiconductor substrate 150.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A solar cell module comprising:
a plurality of solar cells electrically connected to each other, wherein at least one of the plurality of solar cells includes:
a semiconductor substrate;
a plurality of first collecting electrodes provided on a principal surface of the semiconductor substrate; and
a second collecting electrode provided on the principal surface of the semiconductor substrate and connected to the plurality of first collecting electrodes, wherein
the second collecting electrode extends beyond the semiconductor substrate toward an adjacent further solar cell, and
a portion of the second collecting electrode provided on the principal surface of the semiconductor substrate and a portion of the second collecting electrode extending beyond the semiconductor substrate are formed to be integrated with each other.

2. The solar cell module according to claim 1, wherein
the solar cell is a back surface junction type solar cell, and collecting electrodes are not provided on a principal surface of the semiconductor substrate opposite to the principal surface on which the first collecting electrodes and the second collecting electrode are provided.

3. The solar cell module according to claim 1, wherein
collecting electrodes provided on a principal surface of the semiconductor substrate opposite to the principal surface on which the first collecting electrodes and the second electrode are provided do not extend beyond the semiconductor substrate.

4. The solar cell module according to claim 2, wherein
the first collecting electrodes are bonded to an adjacent further solar cell in an area overlapping the adjacent further solar cell using an adhesive.

5. The solar cell module according to claim 2, wherein
the first collecting electrodes are bonded to an adjacent further solar cell in an area overlapping the adjacent further solar cell using an adhesive.

6. A method of manufacturing a solar cell, comprising:
preparing a semiconductor substrate; and
forming a collecting electrode by plating, the collecting electrode being provided on a principal surface of the semiconductor substrate and extending beyond the semiconductor substrate, wherein
the forming forms a portion of the collecting electrode provided on the principal surface of the semiconductor substrate and a portion of the collecting electrode extending beyond the semiconductor substrate to be integrated with each other.

7. The method of manufacturing a solar cell according to claim 6, wherein
the preparing prepares a preparatory semiconductor substrate having a principal surface of a size larger than an size of the principal surface of an ultimate semiconductor substrate, and
the forming includes:
forming the collecting electrode on the principal surface of the preparatory semiconductor substrate by plating; and
cutting a portion of the preparatory semiconductor substrate so as to result in the size of the principal surface of the ultimate semiconductor substrate.

8. The method of manufacturing a solar cell according to claim 6, wherein
the preparing arranges an auxiliary sheet on the semiconductor substrate while aligning the principal surface of the semiconductor substrate and a principal surface of the auxiliary sheet, and
the forming includes:
forming the collecting electrode on the principal surface of the semiconductor substrate and on the principal surface of the auxiliary sheet by plating; and
removing the auxiliary sheet from the semiconductor substrate.
